(19) United States
(12) Patent Application Publication
(10) Pub. No.: US 2025/0379509 A1
(43) Pub. Date: Dec. 11, 2025

(54) MONITORING HEALTH OF A POWER CONVERTER

(71) Applicant: Rolls-Royce Deutschland Ltd & Co KG, Blankenfelde-Mahlow (DE)

(72) Inventors: Viswanathan VAIYAPURI, Singapore (SG); Sivakumar NADARAJAN, Singapore (SG); Mohamed Sathik MOHAMED HALICK, Singapore (SG)

(21) Appl. No.: 19/228,985

(22) Filed: Jun. 5, 2025

(30) Foreign Application Priority Data
Jun. 5, 2024 (GB) 2407961.8

(51) Int. Cl. H02M 1/32; G01R 15/18; H02M 1/00

(52) U.S. Cl. CPC H02M 1/32; G01R 15/181; H02M 1/0029

(57) ABSTRACT

A method for monitoring a health of a power converter having a plurality of power devices includes selecting a first power device and a second power device from the plurality of power devices. The method includes injecting simultaneously a control pulse to only the first power device and the second power device, determining first voltage and current slew rates of the first power device and second voltage and current slew rates of the second power device, and determining a voltage slew rate ratio of the first voltage slew rate to the second voltage slew rate. The method includes determining a current slew rate ratio of the first current slew rate to the second current slew rate, and determining that the power converter is degraded when the voltage and current slew rate ratios lie outside respective predetermined voltage and current slew rate ratio ranges.

This application claims the benefit of UK Patent Application No. 2407961.8, filed on Jun. 5, 2024, which is hereby incorporated by reference in its entirety.

### FIELD

The present embodiments relate to a method for monitoring a health of a power converter.

### BACKGROUND

Electrical devices, such as power converters, are used in a multitude of applications where an efficient management and transformation of electrical energy is required. The power converters may be employed where an alternating current is the primary mode of power delivery, such as in renewable energy integration, vehicular propulsion, and various industrial processes. Despite their role, the power converters may also be susceptible to operational disruptions due to component degradation, which may lead to significant downtime and maintenance costs. The degradation often stems from thermal and electrical stress, particularly affecting the components that are responsible for maintaining system performance and longevity.

Traditional methods for detecting failures in components of the power converters often involve continuous monitoring with high sampling rates and the use of complex algorithms processed by advanced processors. These stipulations may lead to increased costs, complexity, and potential interference with the power converters. Further, existing solutions may not be easily transportable, which may limit their effectiveness during routine checks, service, or maintenance activities.

### SUMMARY AND DESCRIPTION

The scope of the present invention is defined solely by the appended claims and is not affected to any degree by the statements within this summary.

There is a recognized requirement for a more efficient approach to monitor the health of the power converter. Such approach may reduce the demand for continuous data collection and complex processing, while still effectively identifying early signs of wear and potential failures of the power converter.

In accordance with a first aspect of the present disclosure, a method for monitoring a health of a power converter having a plurality of power devices is disclosed. The method includes electrically connecting the power converter to a direct current (DC) voltage supply and a load. The method further includes selecting a first power device and a second power device from the plurality of power devices. The method further includes injecting simultaneously a control pulse to only the first power device and the second power device for a predetermined time duration. The method further includes determining a first voltage slew rate of the first power device and a second voltage slew rate of the second power device. The method further includes determining a first current slew rate of the first power device and a second current slew rate of the second power device. The method further includes determining a voltage slew rate ratio of the first voltage slew rate to the second voltage slew rate. The method further includes determining a current slew rate ratio of the first current slew rate to the second current slew rate. The method further includes determining that the power converter is degraded if: the voltage slew rate ratio lies outside a predetermined voltage slew rate ratio range; the current slew rate ratio lies outside a predetermined current slew rate ratio range; or a combination thereof.

The method of the present disclosure may not interfere with an operation of the power converter. Instead, the method may be performed before a prestart check or during a service or an on-wing inspection/maintenance to monitor the health of the power converter, such as identifying early device aging and failure and thereby predicting component degradation. This may increase availability and improve reliability of the power converter.

The method may further eliminate a need of an equipment health monitoring (EHM) unit on an aircraft, which may reduce a certification demand and a weight of the aircraft. The method may allow maintenance to be scheduled in or other actions to be taken to prevent consequential damages of a power and propulsion system of the aircraft.

The method may not require continuous voltage and current measurement with a high sampling rate. Further, the method may use less data with respect to other conventional condition monitoring approaches to monitor the health of the power converter, such as identifying early device aging and failure. Therefore, the method may be easy to implement. Further, the method may not require a high-end processor. Instead, the method may be executed by a less complex processing unit for monitoring the health of the power converter. Further, the method may be applicable to any type of power converters (e.g., low power converters and high-power converters) having any type of power devices.

In some embodiments, determining the first voltage slew rate of the first power device includes measuring a first voltage across the first power device using a first voltage sensor and determining the first voltage slew rate as a rate of change of the first voltage with respect to time.

In some embodiments, determining the second voltage slew rate of the second power device includes measuring a second voltage across the second power device using a second voltage sensor and determining the second voltage slew rate as a rate of change of the second voltage with respect to time.

The first voltage slew rate and the second voltage slew rate may provide valuable diagnostic information that may be used to detect early signs of degradation or impending failure.

In some embodiments, determining the first current slew rate of the first power device includes measuring a first current through the first power device using a first current sensor and determining the first current slew rate as a rate of change of the first current with respect to time.

In some embodiments, the first current sensor is a Rogowski coil.

In some embodiments, determining the second current slew rate of the second power device includes measuring a second current through the second power device using a second current sensor and determining the second current slew rate as a rate of change of the second current with respect to time.

In some embodiments, the second current sensor is a Rogowski coil.

The first current slew rate and the second current slew rate may provide valuable diagnostic information that may be used to detect early signs of degradation or impending failure. Further, use of the Rogowski coils as the first current sensor and the second current sensor may enable non-intrusive current measurements without requiring a direct electrical connection to circuitry of the power converter. The Rogowski coil may further eliminate the need for any high voltage isolation and reduce complexity and potential safety risks associated with measurement procedure. Further, the Rogowski coil may have an ability to measure rapidly changing currents accurately. The Rogowski coil may further enhance the practicality and efficiency of the method for monitoring the health of the power converter due to its ease of installation around a conductor.

In some embodiments, the control pulse is simultaneously provided to only the first power device and the second power device by a controller of the power converter.

Therefore, the method may use a lesser amount of data with respect to other conventional condition monitoring approaches to monitor the health of the power converter.

In some embodiments, the voltage slew rate ratio and the current slew rate ratio are determined by using a portable health monitoring unit.

The portable health monitoring unit may enable on-site and immediate assessment of the health of the power converter before the prestart check or during the service or the on-wing inspection/maintenance. Further, the portable health monitoring unit may be easily transportable, which may provide effectiveness during routine checks, service, or maintenance activities.

In some embodiments, the portable health monitoring unit is used for determining if the power converter is degraded.

Utilizing the portable health monitoring unit to determine if the power converter is degraded may allow for timely and efficient identification of degradation of the health of the power converter.

In some embodiments, the control pulse has a frequency range from 1 Hertz (Hz) to 1 Megahertz (MHz).

Therefore, the method may not require continuous voltage and current measurement with a high sampling rate.

In some embodiments, the predetermined time duration is based on a duty cycle of the control pulse.

The predetermined time duration based on a duty cycle of the control pulse may provide accurate measurements of the first voltage slew rate and the second voltage slew rate, and the first current slew rate and the second current slew rate.

In some embodiments, the predetermined voltage slew rate ratio range and the predetermined current slew rate ratio range are based on historical data.

This historical data-driven approach may allow for more accurate and reliable identification of deviations over time that may determine degradation or failure of the power converter, leading to improved diagnostic precision.

In some embodiments, the method includes providing an alert upon determining that the power converter is degraded.

The alert may allow timely intervention, which may prevent damage to the power converter and/or downstream components. The alert may also facilitate the scheduling of maintenance or repairs, potentially avoiding unplanned downtime. This may increase availability and improve reliability of the power converter.

In some embodiments, the DC voltage supply is a battery. The battery may include any battery based on desired application attributes.

The method according to the first aspect of the disclosure may include same or similar developments. Therefore, a development of one aspect of the disclosure is also applicable to another aspect of the disclosure.

These and other aspects of the present embodiments will be apparent from and elucidated with reference to the embodiments described hereinafter. The embodiments are described in the following based on the drawings. The drawings are not necessarily intended to represent the embodiments to scale. Drawings are, where useful for explanation, shown in schematized and/or slightly distorted form. With regard to additions to the teachings immediately recognizable from the drawings, reference is made to the relevant state-of-the-art. Numerous modifications and changes may be made to the form and detail of an embodiment without deviating from the general idea of the disclosure.

In addition, all combinations of at least two of the features disclosed in the description, drawings, and/or claims fall within the scope of the disclosure. The general idea of the disclosure is not limited to the exact form or detail of the example embodiments shown and described below, or to an object that would be limited in comparison to the object claimed in the claims. For specified design ranges, values within the specified limits are also disclosed as limit values and thus arbitrarily applicable and claimable.

### BRIEF DESCRIPTION OF THE DRAWINGS

Further advantages, features, and details of the invention result from the following description of example embodiments as well as from the drawings:

FIG. 1 is a schematic block diagram of a power converter health monitoring system, according to an embodiment of the present disclosure;

FIG. 2 is a schematic block diagram of the power converter health monitoring system and a plurality of voltage sensors, according to an embodiment of the present disclosure;

FIG. 3 is a schematic block diagram of the power converter health monitoring system and a plurality of current sensors, according to an embodiment of the present disclosure;

FIG. 4 is a schematic block diagram of a current sensor from the plurality of current sensors, according to an embodiment of the disclosure;

FIG. 5 is a schematic block diagram of the power converter health monitoring system, according to an embodiment of the present disclosure; and

FIG. 6 is a flow chart of a method for monitoring a health of a power converter, according to an embodiment of the present disclosure.

### DETAILED DESCRIPTION

Aspects and embodiments of the present disclosure will now be discussed with reference to the accompanying figures. Further aspects and embodiments will be apparent to those skilled in the art.

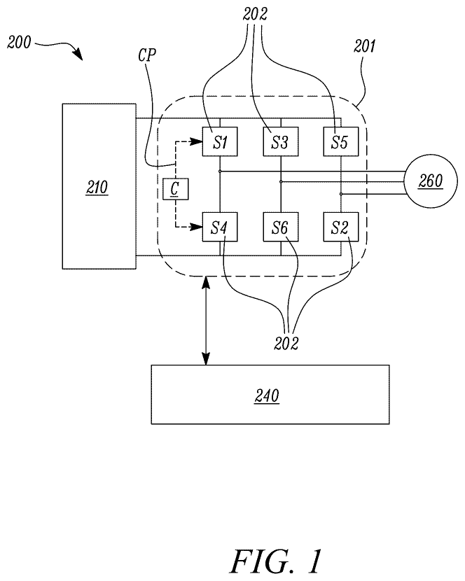

FIG. 1 shows a schematic block diagram of a power converter health monitoring system 200, according to an embodiment of the present disclosure.

The power converter health monitoring system 200 includes a power converter 201. In the illustrated embodiment of FIG. 1, the power converter 201 is a three-phase inverter. However, in some other embodiments, the power converter 201 may be any power converter based on desired application attributes.

The power converter 201 is electrically connected to a direct current (DC) voltage supply 210. The DC voltage supply 210 is configured to provide a DC power to the power converter 201. In some embodiments, the DC voltage supply 210 is a battery. In some embodiments, the DC voltage supply 210 may be a rectifier. Further, the power converter 201 is electrically connected to a load 260. In some embodiments, the load 260 may be a three-phase motor. In some embodiments, the load 260 may be a propulsion motor.

The power converter health monitoring system 200 further includes a portable health monitoring unit 240. The portable health monitoring unit 240 is communicably connected to the power converter 201.

The power converter 201 includes a plurality of power devices 202 and a controller C. In the illustrated embodiment of FIG. 1, the power converter 201 includes six power devices S1, S2, S3, S4, S5, and S6. However, in some other embodiments, the power converter 201 may include any number of power devices 202 based on desired application attributes. The controller C is communicably connected to each power device 202 of the plurality of power devices 202. The plurality of power devices 202 may include insulated-gate bipolar transistors (IGBT) devices, silicon carbide (SiC) devices, and Gallium nitride (GaN) devices.

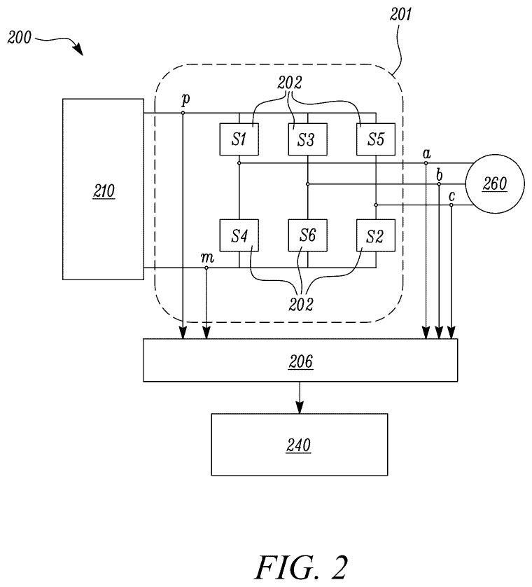

FIG. 2 shows a schematic block diagram of the power converter health monitoring system 200, according to an embodiment of the present disclosure. FIG. 2 further illustrates a plurality of voltage sensors 206 configured to measure electrical voltages across a corresponding plurality of power devices 202. In some embodiments, each voltage sensor 206 of the plurality of voltage sensors 206 may be a high bandwidth voltage sensor.

In the illustrated example of FIG. 2, points p, m, a, b, and c are shown electrically connected to the plurality of voltage sensors 206. In order to measure a voltage across the power device S1, the point p and the point a may be electrically connected to a corresponding voltage sensor from the plurality of voltage sensors 206, and in order to measure a voltage across the power device S2, the point m and the point c may be electrically connected to a corresponding voltage sensor from the plurality of voltage sensors 206. Similarly, in order to measure a voltage across the power device S3, the point p and the point b may be electrically connected to a corresponding voltage sensor 206 from the plurality of voltage sensors 206, and in order to measure a voltage across the power device S4, the point m and the point a may be electrically connected to a corresponding voltage sensor 206 from the plurality of voltage sensors 206. Further, in order to measure a voltage across the power device S5, the point p and the point c may be electrically connected to a corresponding voltage sensor from the plurality of voltage sensors 206, and in order to measure a voltage across the power device S6, the point m and the point b may be electrically connected to a corresponding voltage sensor from the plurality of voltage sensors 206. In the illustrated example of FIG. 2, each voltage sensor 206 of the plurality of voltage sensors 206 is communicably connected to the portable health monitoring unit 240.

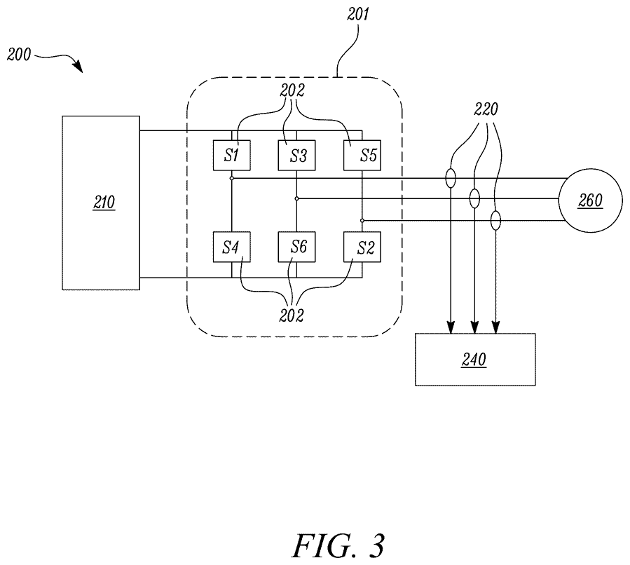

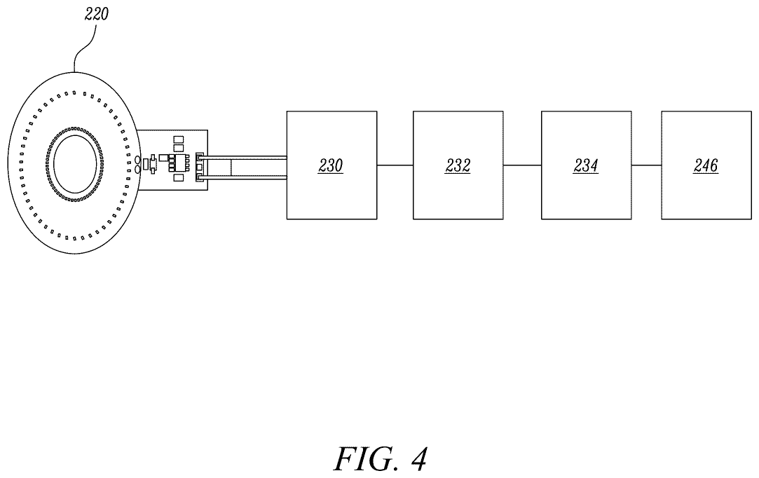

FIG. 3 shows a schematic block diagram of the power converter health monitoring system 200, according to an embodiment of the present disclosure. FIG. 3 further illustrates a plurality of current sensors 220 configured to measure electrical currents through corresponding plurality of power devices 202. FIG. 4 shows a schematic block diagram of a current sensor 220 from the plurality of current sensors 220, according to an embodiment of the disclosure.

Referring to FIGS. 3 and 4, the plurality of current sensors 220 may be clamped onto terminals of the load 260 for sensing currents through the power devices 202. After being clamped, the current sensors 220 may send sensed current signals to an integrator 230 configured to accumulate the current signals over time. Further, an amplifier 232 may amplify the current signals, and a filter 234 may remove unnecessary high frequency noise or interference from the current signals.

In the illustrated embodiment of FIGS. 3 and 4, each current sensor 220 of the plurality of current sensors 220 is a Rogowski coil. Such current sensors 220 may not require any high voltage isolation. Further, the plurality of current sensors 220 may have no physical or direct connection with the power converter health monitoring system 200.

In the illustrated embodiment of FIG. 3, each current sensor 220 of the plurality of current sensors 220 is communicably connected to the portable health monitoring unit 240. The portable health monitoring unit 240 further includes a processor 246. The processor 246 of the portable health monitoring unit 240 may further process the current signals received from the filter 234.

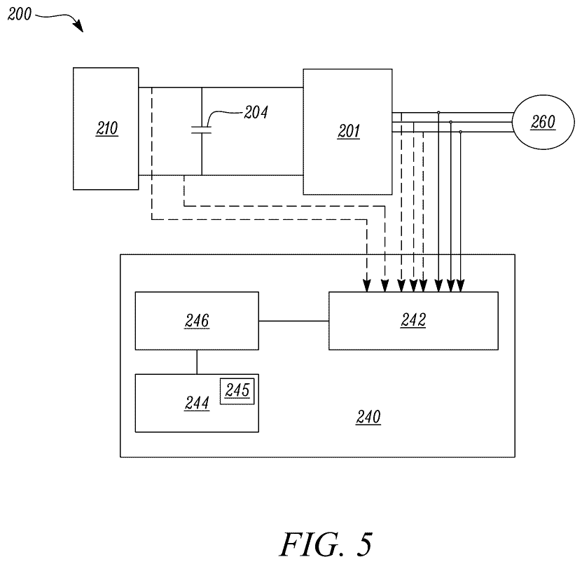

FIG. 5 shows a schematic block diagram of the power converter health monitoring system 200, according to an embodiment of the present disclosure. Specifically, the portable health monitoring unit 240 is shown in more detail in FIG. 5.

In some embodiments, the power converter health monitoring system 200 further includes a capacitor 204 electrically connected in parallel with the plurality of power devices 202. In some embodiments, the capacitor 204 is a DC link capacitor. In some cases, the DC voltage supply 210 may introduce parasitic inductance in the power converter 201. For example, when the DC voltage supply 210 is the rectifier, the DC voltage supply 210 may introduce its own harmonics into the power converter 201. In such cases, the capacitor 204 may be used to eliminate the harmonics and provide a fundamental component to the power converter 201. Hence, the capacitor 204 may play an important role in the operation of the power converter 201.

In some embodiments, the portable health monitoring unit 240 includes a circuit 242. The circuit 242 is configured to calculate various electrical parameters for the power converter 201 based on the measured electrical currents and voltages received from the plurality of current sensors 220 and the plurality of voltage sensors 206, respectively.

In some embodiments, the processor 246 is communicably coupled to the circuit 242. The processor 246 is configured to execute a plurality of instructions to perform operations described herein. The processor 246 may be further configured to generate an alert 245 when the power converter 201 is degraded.

In some embodiments, the portable health monitoring unit 240 further includes a display 244 communicably coupled to the processor 246. The display 244 may be configured to display the alert 245 when the power converter 201 is degraded.

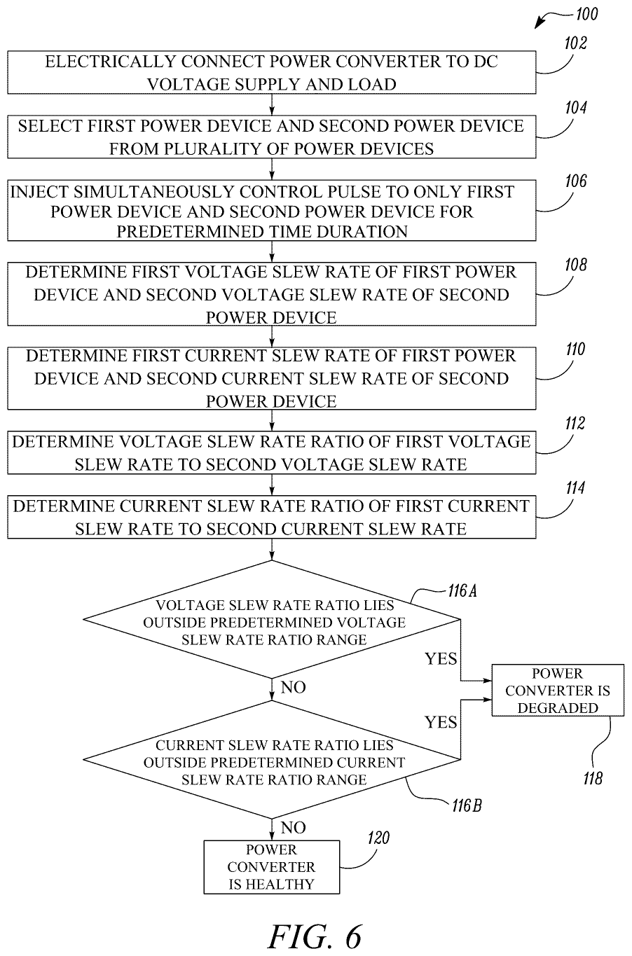

FIG. 6 shows a flow chart for a method 100 for monitoring the health of the power converter 201 having the plurality of power devices 202, according to an embodiment of the present disclosure. The method 100 will further be described with reference to FIGS. 1 to 6. In some embodiments, the processor 246 may perform the method 100 described herein. In some embodiments, the processor 246 may perform the method 100 when a trigger is provided by a user, such as a pilot or a maintenance person. The method 100 for monitoring the health of the power converter 201 is performed before a prestart check or during a service or an on-wing inspection/maintenance.

At act 102, the method 100 includes electrically connecting the power converter 201 to the DC voltage supply 210 and the load 260.

At act 104, the method 100 includes selecting a first power device and a second power device from the plurality of power devices 202. For example, the power device S1 may be selected as the first power device, and the power device S4 may be selected as the second power device.

At act 106, the method 100 includes injecting simultaneously a control pulse CP to only the first power device and the second power device for a predetermined time duration. In other words, the method 100 includes injecting simultaneously the control pulse CP to only two selected power devices 202 from the plurality of power devices 202. For example, the power devices S1 and the power device S4 may be injected simultaneously the control pulse CP for the predetermined time duration.

In some embodiments, the control pulse CP is simultaneously provided to only the first power device (e.g., the first power device S1) and the second power device (e.g., the second power device S4), for example, by the controller C of the power converter 201. Further, in some embodiments, the control pulse CP has a frequency range from 1 Hertz (Hz) to 1 Megahertz (MHz). In some embodiments, the predetermined time duration is based on a duty cycle of the control pulse CP. The control pulse CP is simultaneously provided to only the first power device and the second power device, for example, by the controller C of the power converter 201 before the pre-start check or during the service, or the on-wing inspection/maintenance.

At act 108, the method 100 includes determining a first voltage slew rate of the first power device and a second voltage slew rate of the second power device. For example, the first voltage slew rate of the power device S1 and the second voltage slew rate of the power device S4 may be determined.

In some embodiments, the first voltage slew rate of the first power device and the second voltage slew rate of the second power device may be determined by using the portable health monitoring unit 240. In some embodiments, the first voltage slew rate of the first power device and the second voltage slew rate of the second power device may be determined by the processor 246 of the portable health monitoring unit 240.

In some embodiments, determining the first voltage slew rate of the first power device further includes measuring a first voltage across the first power device using a first voltage sensor and determining the first voltage slew rate as a rate of change of the first voltage with respect to time. Similarly, in some embodiments, determining the second voltage slew rate of the second power device includes measuring a second voltage across the second power device using a second voltage sensor and determining the second voltage slew rate as a rate of change of the second voltage with respect to time.

The first voltage sensor and the second voltage sensor may be the voltage sensors 206 from the plurality of voltage sensors 206 shown in FIG. 2. For example, for measuring the first voltage across the first power device (e.g., the power device S1), the first voltage sensor may be disposed between the points p, a. Similarly, for measuring the second voltage across the second power device (e.g., the power device S4), the second voltage sensor may be disposed between the points m, a.

At act 110, the method 100 includes determining a first current slew rate of the first power device and a second current slew rate of the second power device. For example, the first current slew rate of the power device S1 and the second current slew rate of the power device S4 may be determined.

In some embodiments, the first current slew rate of the first power device and the second current slew rate of the second power device may be determined by using the portable health monitoring unit 240. In some embodiments, the first current slew rate of the first power device and the second current slew rate of the second power device may be determined by the processor 246 of the portable health monitoring unit 240.

In some embodiments, determining the first current slew rate of the first power device includes measuring a first current through the first power device using a first current sensor and determining the first current slew rate as a rate of change of the first current with respect to time. In some embodiments, the first current sensor is a Rogowski coil.

In some embodiments, determining the second current slew rate of the second power device includes measuring a second current through the second power device using a second current sensor and determining the second current slew rate as a rate of change of the second current with respect to time. In some embodiments, the second current sensor is a Rogowski coil.

The first current sensor and the second current sensor may be the current sensors from the plurality of current sensors 220 shown in FIG. 3. For example, for measuring the first current through the first power device (e.g., the power device S1), the first current sensor may be electrically connected between the power device S1 and the load 260. Similarly, for measuring the second current through the second power device (e.g., the power device S4), the second current sensor may be electrically connected between the power device S4 and the load 260.

At act 112, the method 100 includes determining a voltage slew rate ratio of the first voltage slew rate to the second voltage slew rate.

At act 114, the method 100 includes determining a current slew rate ratio of the first current slew rate to the second current slew rate.

In some embodiments, the voltage slew rate ratio and the current slew rate ratio are determined by using the portable health monitoring unit 240. In some embodiments, the voltage slew rate ratio and the current slew rate ratio are determined by the processor 246 of the portable health monitoring unit 240.

At act 116A, the method 100 includes determining if the voltage slew rate ratio lies outside a predetermined voltage slew rate ratio range. If the voltage slew rate ratio lies outside the predetermined voltage slew rate ratio range, the method 100 proceeds to act 118. Otherwise, the method 100 proceeds to act 116B.

At act 116B, the method 100 includes determining if the current slew rate ratio lies outside a predetermined current slew rate ratio range. If the current slew rate ratio lies outside the predetermined current slew rate ratio range, the method 100 proceeds to act 118. Otherwise, the method 100 proceeds to act 120.

At act 118, the method 100 includes determining that the power converter is degraded (e.g., if the voltage slew rate ratio lies outside the predetermined voltage slew rate ratio range and/or if the current slew rate ratio lies outside the predetermined current slew rate ratio range). In some embodiments, the method 100 further includes providing the alert 245 (shown in FIG. 5) upon determining that the power converter 201 is degraded.

At act 120, the method 100 includes determining that the power converter is healthy (e.g., if the voltage slew rate ratio lies within the predetermined voltage slew rate ratio range and the current slew rate ratio lies within the predetermined current slew rate ratio range).

In some embodiments, the portable health monitoring unit 240 is further used for determining if the power converter 201 is degraded. In some embodiments, the predetermined voltage slew rate ratio range and the predetermined current slew rate ratio range are based on historical data. The historical data may be stored in a memory (not shown) of the portable health monitoring unit 240. The memory may be communicably connected to the processor 246 of the portable health monitoring unit 240. It may be assumed that a 10% to 20% change from an initial value is a sign of a degradation or a failure.

The method 100 may not interfere with an operation of the power converter 201. Instead, the method 100 may be performed before the prestart check or during the service or the on-wing inspection/maintenance to monitor the health of the power converter 201, such as identifying early device aging and failure and thereby predicting component degradation. This may increase availability and improve reliability of the power converter 201.

The method 100 may further eliminate a need of an equipment health monitoring (EHM) unit on an aircraft, which may reduce a certification demand and a weight of the aircraft. The method 100 may allow maintenance to be scheduled or other actions to be taken to prevent consequential damages of a power and propulsion system of the aircraft.

The method 100 may not require continuous voltage and current measurement with a high sampling rate. Further, the method 100 may use a lesser amount of data with respect to other conventional condition monitoring approaches to monitor the health of the power converter 201, such as identifying early device aging and failure. Therefore, the method 100 may be easy to implement. Further, the method may not require a high-end processor. Instead, the method may be executed by a less complex processing unit (e.g., the processor 246) for monitoring the health of the power converter 201. Further, the method 100 may be applicable to any type of power converters 201 (e.g., low power converters and high-power converters) having any type of power devices 202.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for monitoring health of a power converter having a plurality of power devices, the method comprising:
electrically connecting the power converter to a direct current (DC) voltage supply and a load;
selecting a first power device and a second power device from the plurality of power devices;
injecting simultaneously a control pulse to only the first power device and the second power device for a predetermined time duration;
determining a first voltage slew rate of the first power device and a second voltage slew rate of the second power device;
determining a first current slew rate of the first power device and a second current slew rate of the second power device;
determining a voltage slew rate ratio of the first voltage slew rate to the second voltage slew rate;
determining a current slew rate ratio of the first current slew rate to the second current slew rate; and
determining that the power converter is degraded when:
the voltage slew rate ratio lies outside a predetermined voltage slew rate ratio range;
the current slew rate ratio lies outside a predetermined current slew rate ratio range; or
a combination thereof.

2. The method of claim 1, wherein determining the first voltage slew rate of the first power device comprises:
measuring a first voltage across the first power device using a first voltage sensor; and
determining the first voltage slew rate as a rate of change of the first voltage with respect to time.

3. The method of claim 1, wherein determining the second voltage slew rate of the second power device further comprises:
measuring a second voltage across the second power device using a second voltage sensor; and
determining the second voltage slew rate as a rate of change of the second voltage with respect to time.

4. The method of claim 1, wherein determining the first current slew rate of the first power device comprises:
measuring a first current through the first power device using a first current sensor; and
determining the first current slew rate as a rate of change of the first current with respect to time.

5. The method of claim 4, wherein the first current sensor is a Rogowski coil.

6. The method of claim 4, wherein determining the second current slew rate of the second power device comprises:
measuring a second current through the second power device using a second current sensor; and
determining the second current slew rate as a rate of change of the second current with respect to time.

7. The method of claim 6, wherein the second current sensor is a Rogowski coil.

8. The method of claim 1, wherein the control pulse is simultaneously provided to only the first power device and the second power device by a controller of the power converter.

9. The method of claim 1, wherein the voltage slew rate ratio and the current slew rate ratio are determined using a portable health monitoring unit.

10. The method of claim 9, wherein the portable health monitoring unit is configured to determine when the power converter is degraded.

11. The method of claim 1, wherein the control pulse has a frequency range from 1 Hertz to 1 Megahertz.

12. The method of claim 1, wherein the predetermined time duration is based on a duty cycle of the control pulse.

13. The method of claim 1, wherein the predetermined voltage slew rate ratio range and the predetermined current slew rate ratio range are based on historical data.

14. The method of claim 1, further comprising providing an alert when the power converter is determined to be degraded.

15. The method of claim 1, wherein the DC voltage supply is a battery.
